(19) United States
(12) Patent Application Publication
(10) Pub. No.: US 2016/0211151 A1
(43) Pub. Date: Jul. 21, 2016

(54) SUBSTRATE PROCESSING APPARATUS AND METHOD OF MANUFACTURING SEMICONDUCTOR DEVICE

(71) Applicant: HITACHI KOKUSAI ELECTRIC INC., Tokyo (JP)

(72) Inventors: Yasutoshi TSUBOTA, Toyama-shi (JP); Yuichi WADA, Toyama-shi (JP); Kenji KAMEDA, Toyama-shi (JP); Shin HIYAMA, Toyama-shi (JP)

(73) Assignee: HITACHI KOKUSAI ELECTRIC INC., Tokyo (JP)

(21) Appl. No.: 15/005,981

(22) PCT Filed: Jul. 26, 2013
(86) PCT No.: PCT/JP2013/070342

§ 371 Date: Jan. 25, 2016

(51) Int. Cl. H01L 21/3213; H01J 37/32; H01L 21/67

(52) U.S. Cl. CPC H01L 21/32135; H01L 21/67253; H01L 21/67069; H01L 21/67109; H01L 21/67248; H01J 37/32724; H01J 37/32834; H01J 37/32449

(57) ABSTRACT

Etching having high selectivity is performed within a plane of a substrate. To this end, a substrate processing apparatus includes a substrate support where a substrate including a first film containing at least silicon and a second film having a silicon content ratio lower than that of the first film is placed; a process chamber wherein the substrate support is disposed; a gas supply system configured to supply an etching gas to the substrate; a coolant channel disposed in the substrate support and having a coolant flowing therein; a coolant flow rate controller configured to control a flow rate of the coolant supplied to the coolant channel; a control unit configured to control at least the coolant flow rate controller such that a temperature of the substrate is maintained whereat an etch rate of the first film is higher than that of the second film while the etching gas is in contact with the substrate; and an exhaust system configured to exhaust an inner atmosphere of the process chamber.

### CROSS-REFERENCE TO RELATED PATENT APPLICATION

This U.S. non-provisional patent application claims priority under 35 U.S.C. §119 of International Application No. PCT/JP2013/070342, filed on Jul. 26, 2013, in the WIPO, the entire contents of which are hereby incorporated by reference.

### BACKGROUND OF THE INVENTION

1. Field of the Invention

The present invention relates to a substrate processing apparatus related to dry etching and a method of manufacturing a semiconductor device.

2. Description of the Related Art

For higher integration of a semiconductor device, patterns have been developed to be finer. To obtain a fine pattern, various methods using a process of forming a sacrificial film or an etching process have been taken into account. A pattern including ultra fine grooves or pillars may be formed by using these processes.

An example of the etching method includes wet etching or plasma dry etching. Dry etching has been disclosed, for example, in Patent document 1.

### RELATED ART DOCUMENT

### Patent Document

1 Japanese Unexamined Patent Application Publication No. 2011-44493

In order to form a high-quality fine pattern, the distance between adjacent patterns, the strength of a pattern, the uniformity of a pattern, etc. should be taken into account. Therefore, an etching method having high selectivity within a plane of a substrate is required.

### SUMMARY OF THE INVENTION

According to one aspect of the present invention, a substrate processing apparatus includes a substrate support where a substrate including a first film containing at least silicon and a second film having a silicon content ratio lower than that of the first film is placed; a process chamber wherein the substrate support is disposed; a gas supply system configured to supply an etching gas to the substrate; a coolant channel disposed in the substrate support and having a coolant flowing therein; a coolant flow rate controller configured to control a flow rate of the coolant supplied to the coolant channel; a control unit configured to control at least the coolant flow rate controller such that a temperature of the substrate is maintained whereat an etch rate of the first film is higher than that of the second film while the etching gas is in contact with the substrate; and an exhaust system configured to exhaust an inner atmosphere of the process chamber.

According to another aspect of the present invention, a method of manufacturing a semiconductor device includes (a) placing a substrate including a first film containing at least silicon and a second film having a silicon content ratio lower than that of the first film on a substrate support in a process chamber; (b) supplying an etching gas, controlling a flow rate of a coolant flowing in a coolant channel disposed in the substrate support such that a temperature of the substrate is maintained whereat an etch rate of the first film is higher than that of the second film while the etching gas is in contact with the substrate, and exhausting an inner atmosphere of the process chamber; and (c) unloading the substrate from the process chamber.

### BRIEF DESCRIPTION OF THE DRAWINGS

FIG. 1 is a schematic horizontal cross-sectional view of a substrate processing apparatus according to an embodiment of the present invention.

FIG. 2 is a schematic vertical cross-sectional view of a substrate processing apparatus according to an embodiment of the present invention.

FIG. 3 is a vertical cross-sectional view of a process unit included in a substrate processing apparatus according to an embodiment of the present invention.

FIG. 4 is a vertical cross-sectional view of a susceptor included in a process unit according to an embodiment of the present invention.

FIG. 5 is a diagram illustrating the structure of a controller according to an embodiment of the present invention.

FIGS. 6A and 6B are vertical cross-sectional views of a device processed by a substrate processing apparatus according to an embodiment of the present invention.

FIG. 7 is a flowchart illustrating a process flow according to an embodiment of the present invention.

FIGS. 8A through 8C are vertical cross-sectional views of a device processed by a substrate processing apparatus according to an embodiment of the present invention.

FIGS. 9A through 9C are vertical cross-sectional views of a device processed by a substrate processing apparatus according to yet another embodiment of the present invention.

### DETAILED DESCRIPTION OF THE EMBODIMENTS

Next, embodiments of the present invention will be described with reference to the accompanying drawings. The present invention relates to, for example, a substrate processing method employed by a semiconductor manufacturing device. In particular, the present invention also relates to a substrate processing method in which etching is performed by supplying a reactive gas to a surface of a substrate.

### First Embodiment

### Substrate Processing Apparatus

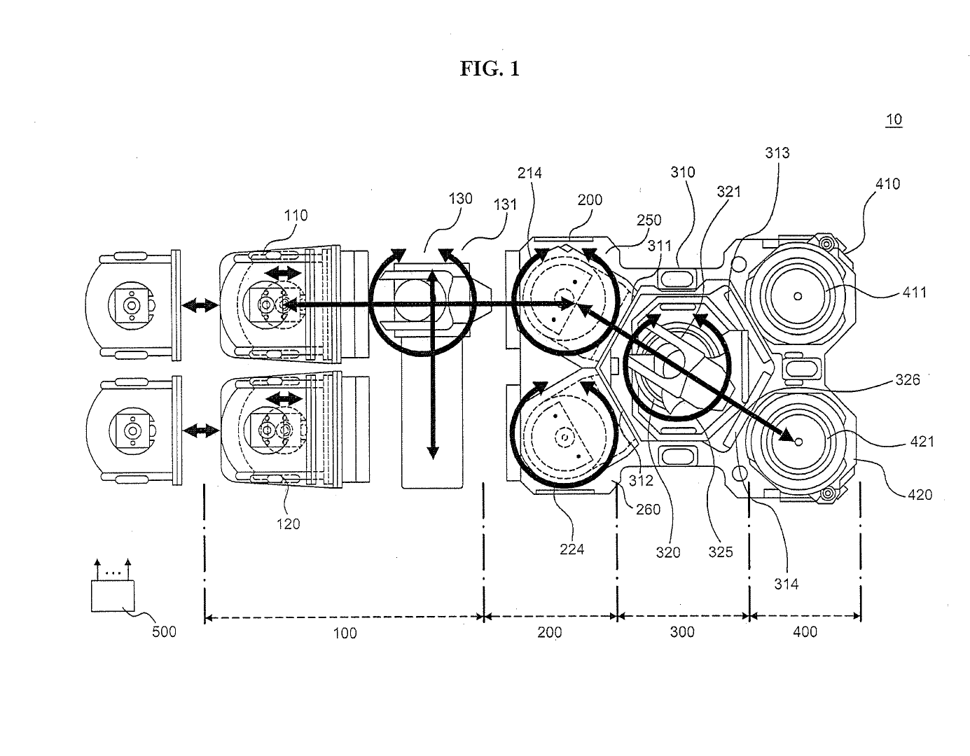

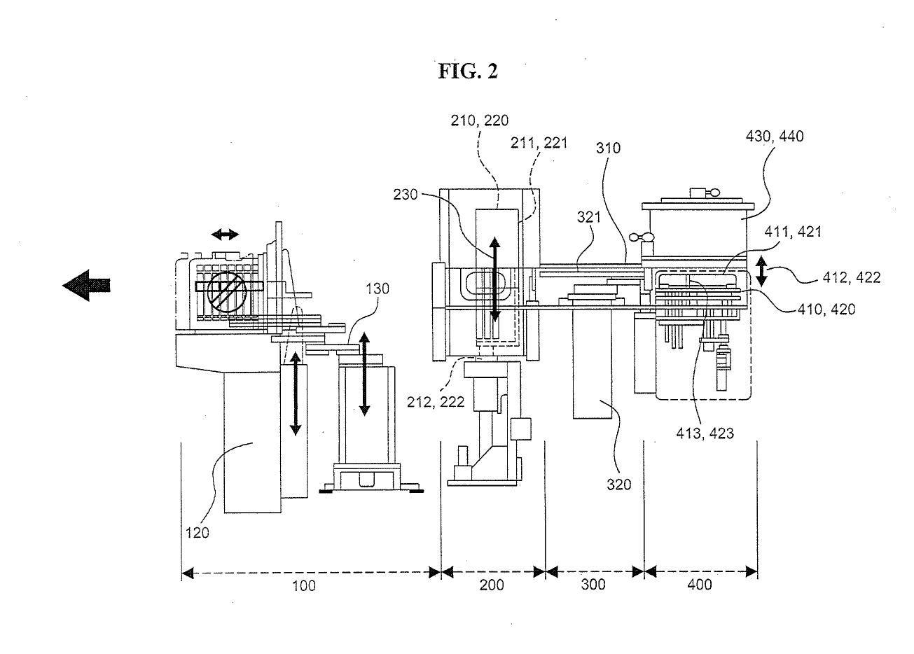

In one embodiment of the present invention, a method of manufacturing a semiconductor device and a substrate processing method are performed by an etching apparatus used as a semiconductor manufacturing apparatus or a substrate processing apparatus. FIG. 1 is a schematic horizontal cross-sectional view of an etching apparatus according to an embodiment of the present invention. FIG. 2 is a schematic vertical cross-sectional view of an etching apparatus according to an embodiment of the present invention. As illustrated in FIGS. 1 and 2, an etching apparatus 10 includes an equipment front end module (EFEM) 100, a load lock chamber unit 200, a transfer module unit 300, and a process chamber unit 400 used as a process chamber configured to perform etching therein.

The EFEM 100 includes front opening unified pods (FOUPs) 110 and 120 and a standby transfer robot 130 which is a first transfer unit configured to transfer a wafer from each of the FOUPs 110 and 120 to the load lock chamber. In the FOUPs 110 and 120, 25 wafers 600 which are substrates are loaded. Five wafers 600 among the 25 wafers 600 are unloaded from the FOUPs 110 and 120 at a time by an aim unit of the standby transfer robot 130.

The load lock chamber unit 200 includes load lock chambers 250 and 260, and buffer units 210 and 220 configured to retain wafers 600, which are transferred from the FOUPs 110 and 120, in the load lock chambers 250 and 260. The buffer units 210 and 220 include boats 211 and 221, and index assemblies 212 and 222 located below the boats 211 and 221. The boats 211 and 221 and the index assemblies 212 and 222 located below the boats 211 and 221 are simultaneously rotated about θ-axis 214 and 224.

The transfer module unit 300 includes a transfer module 310 used as a transfer chamber. The load lock chambers 250 and 260 described above are installed in the transfer module 310 via gate valves 311 and 312. In the transfer module 310, a vacuum arm robot unit 320 used as a second transfer unit is installed.

The process chamber unit 400 includes process units 410 and 420. The process units 410 and 420 are installed in the transfer module 310 via gate valves 313 and 314.

The process units 410 and 420 include susceptor tables 411 and 421 configured to accommodate wafers 600 (which will be described below) thereon. Lifter pins 413 and 423 are installed to respectively pass through the susceptor tables 411 and 421. The lifter pins 413 and 423 are moved upward/downward in a direction of z-axis 412 and 422. The process units 410 and 420 further include gas buffer spaces 430 and 440.

As will be described below, the gas buffer spaces 430 and 440 respectively include walls 431 and 441 each forming a space. Gas supply holes are respectively formed in the tops of the gas buffer spaces 430 and 440.

The etching apparatus 10 further includes a controller 500 electrically connected to the other elements of the etching apparatus 10. The controller 500 controls operations of the other elements.

In the etching apparatus 10 described above, the wafers 600 are transferred from the FOUPs 110 and 120 to the load lock chambers 250 and 260. In this case, as illustrated in FIG. 2, first, the standby transfer robot 130 stores tweezers in pods of the FOUPs 110 and 120 and places five wafers 600 on the tweezers. In this case, the tweezers and of the standby transfer robot 130 are moved upward or downward according to the positions of the wavers 600 to be discharged in a height direction of the wafers 600.

After the wafers 600 are placed on the tweezers, the standby transfer robot 130 is rotated in a direction of a θ-axis 131 to place the wafers 600 on the boats 211 and 221 of the buffer units 210 and 220. In this case, the boats 211 and 221 are operated in a direction of a z-axis 230 to receive the 25 wafers 600 from the standby transfer robot 130. After the 25 wafers 600 are received, the boats 211 and 221 are operated in the direction of the z-axis 230 to adjust the position of the wafer 600 located on a lowest tier of the boats 211 and 221 to a position corresponding to the height of the transfer module unit 300.

In the load lock chambers 250 and 260, a wafer 600 retained by the buffer units 210 and 220 inside the load lock chambers 250 and 260 is loaded on a finger 321 of the vacuum arm robot unit 320. The wafers 600 are transferred onto the susceptor tables 411 and 421 in the process units 410 and 420 by rotating the vacuum arm robot unit 320 in a direction of a θ-axis 325 and extending the finger 321 in a direction of a Y-axis 326.

Hereinafter, an operation of the etching apparatus 10 when the wafers 600 are transferred from the finger 321 to the susceptor tables 411 and 421 will be described.

The wafers 600 are transferred onto the susceptor tables 411 and 421 by using the finger 321 of the vacuum arm robot unit 320 along with the lifter pins 413 and 423. Also, the processed wafer 600 are transferred from the susceptor tables 411 and 421 to the buffer units 210 and 220 inside the load lock chambers 250 and 260 by the vacuum arm robot unit 320 in a manner opposite to the transfer of the wafers 600 onto the susceptor tables 411 and 421.

In the etching apparatus 10 described above, the waters 600 are transferred to the load lock chambers 250 and 260. The insides of the load lock chambers 250 and 260 are vacuum-suctioned (vacuum-replaced). The wafers 600 are transferred to the process units 410 and 420 from the load lock chambers 250 and 260 via the transfer module 310. In the process units 410 and 420, an object to be etched is removed from the wafers 600 (a removing process), and the wafers 600 from which the object to be etched is removed are transferred again to the load lock chambers 250 and 260 via the transfer module 310.

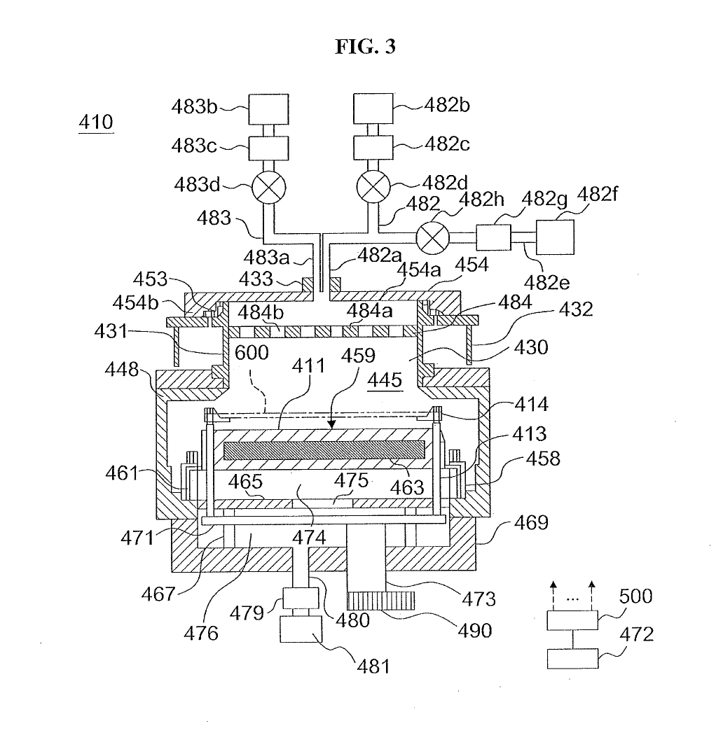

(Process unit of substrate processing apparatus) FIG. 3 is a detailed diagram of the process unit 410 and will be described below. Also, the process unit 420 described above has substantially the same structure as the process unit 410.

The process unit 410 is a process unit configured to etch a semiconductor substrate or a semiconductor device. As illustrated in FIG. 3, the process unit 410 includes the gas buffer chamber 430, and a process chamber 445 configured to accommodate the wafers 600 such as semiconductor substrates, etc. For example, the gas buffer chamber 430 is located at the top of a base plate 448 which is a horizontal frame, and the process chamber 445 is located at the bottom of the base plate 448.

A reactive gas is supplied into the gas buffer chamber 430 via a gas introduction port 433. The wall 431 of the gas buffer chamber 430 is a so-called chamber having a cylindrical shape formed of high-purity quartz glass or ceramic. The wall 431 is disposed such that an axis thereof is located in a vertical direction, and, the top and bottom ends of the top wall 431 are air-tightly sealed by a top plate 454 and the process chamber 445 installed in a direction different from that of the top plate 454. The top plate 454 is supported on the wall 431 and the top of an external shield 432.

The top plate 454 includes a cover unit 454a configured to close one end of the wall 431 and a support unit 454b configured to support the cover unit 454a.

The gas introduction port 433 is installed at a roughly central location of the cover unit 454a. An O-ring 453 is installed between a front end and flange portion of the wall 431 and the support unit 454b to air-tightly seal the gas buffer chamber 430.

A susceptor 459 serving as a substrate support supported by a plurality of pillars 461, e.g., four pillars 461, is installed at a bottom surface of the process chamber 445 below the wall 431. In the susceptor 459, the susceptor table 411, a heater 463 installed in the susceptor 459 and serving as a substrate heating unit configured to heat wafers 600 on the susceptor 459, and a susceptor coolant channel 464 which will be described below are provided.

An exhaust plate 465 is disposed below the susceptor 459. The exhaust plate 465 is supported on a bottom plate 469 via a guide shaft 467. The bottom plate 469 is air-tightly installed at a bottom surface of the process chamber 445. A lifting plate 471 is installed such that the guide shaft 467 is movable upward or downward as a guide. The lifting plate 471 supports at least three lifter pins 413.

As illustrated in FIG. 3, the lifter pins 413 pass through the susceptor table 411 of the susceptor 459. A support unit 414 configured to support a wafer 600 is installed at the top of the lifter pins 413. The support unit 414 extends in a direction toward a center of the susceptor 459. By moving the lifter pins 413 upward or downward, a wafer 600 may be placed on the susceptor table 411 or lifted from the susceptor table 411.

A lifting shaft 473 of a lifting driving unit 490 is connected to the lifting plate 471 via the bottom plate 469. When the lifting driving unit moves the lifting shaft 473 upward or downward, the support unit 414 is moved upward or downward via the lifting plate 471 and the lifter pins 413. Also, FIG. 3 illustrates the lifter pins 413 on which the support unit 414 is disposed.

A baffle ring 458 is installed between the susceptor 459 and the exhaust plate 465. A first exhaust chamber 474 is formed by the baffle ring 458, the susceptor 459 and the exhaust plate 465. A plurality of ventholes are uniformly formed in the baffle ring 458 having a cylindrical shape. Thus, the first exhaust chamber 474 is differentiated from the process chamber 445 and communicates with the process chamber 445 via the plurality of ventholes.

An exhaust communication hole 475 is installed in the exhaust plate 465. The first exhaust chamber 474 and a second exhaust chamber 476 communicate with each other via the exhaust communication hole 475. The second exhaust chamber 476 communicates with an exhaust pipe 480 extending in a direction of gravity. A pressure control valve (automatic pressure controller (APC) valve) 479 and an exhaust pump 481 are installed at the exhaust pipe 480 from an upstream end. When the exhaust pipe 480 is installed below the susceptor 459 and in the direction of gravity, a supplied gas does not remain in the process chamber 445 and is exhausted. Thus, risks that will occur when a user is in contact with the gas during maintenance of the process unit 410 may be lowered. A gas exhaust unit includes at least the exhaust pipe 480 and the pressure control valve 479. The exhaust pump 481 may be further included in the gas exhaust unit.

The top plate 454 above the wall 431 is connected to a first gas supply unit 482 and a second gas supply unit 483. The first gas supply unit (first gas supplier) 482 includes a gas supply pipe 482a connected to the gas introduction port 433 and an inert gas supply pipe 482e connected to the gas supply pipe 482a. A first gas source 482b is connected to an upstream side of the gas supply pipe 482a. A mass flow controller 482c and an opening/closing valve 482d are installed at the gas supply pipe 482a from the upstream end. An inert gas source 482f is connected to an upstream side of the inert gas supply pipe 482e. A mass flow controller 482g and an opening/closing valve 482h are installed at the inert gas supply pipe 482e from the upstream end.

A flow rate of a first gas is controlled by controlling the mass flow controller 482c and the opening/closing valve 482d. Also, a flow rate of an inert gas is controlled by controlling the mass flow controller 482g and the opening/closing valve 482h. The inert gas is used as a purge gas for purging a residual gas in the gas supply pipe 482a or a carrier gas of the first gas to be supplied to the gas supply pipe 482a.

The first gas supply unit 482 includes at least the gas supply pipe 482a, the mass flow controller 482c and the opening/closing valve 482d. The first gas supply unit 482 may further include the inert gas supply pipe 482e, the mass flow controller 482g and the opening/closing valve 482h. The first gas source 482b and the inert gas source 482f may be further included in the first gas supply unit 482.

As the first gas, for example, chlorine trifluoride (ClF₃), xenon difluoride (XeF₂), bromine trifluoride (BrF₃), bromine pentafluoride (BrF₅), iodine heptafluoride (IF₇), or iodine pentafluoride (IF₅) is used.

The second gas supply unit 483 is connected to the top plate 454 above the wall 431 to be adjacent to the first gas supply unit 482. The gas supply unit (second gas supplier) 483 includes a gas supply pipe 483a connected to the gas introduction port 433. A second gas source 483b is connected to an upstream side of the gas supply pipe 483a. At the gas supply pipe 483a, a mass flow controller 483c and an opening/closing valve 483d are installed from the upstream end.

A flow rate of a gas is controlled by controlling the mass flow controller 483c and the opening/closing valve 483d. The second gas supply unit 483 includes at least the gas supply pipe 483a, the mass flow controller 483c and the opening/closing valve 483d. The second gas supply unit 483 may further include the second gas source 483b.

As a second gas, for example, an inert gas such as nitrogen (N₂), etc. is used. The inert gas is used as a dilution gas of the first gas or a gas for purging a residual gas in the process chamber 445.

In the present embodiment, the gas introduction port 433 which is a common gas introduction port is used as a supply hole of the first gas supply unit and the second gas supply unit, but the present invention is not limited thereto and different gas supply holes may be installed to correspond to the first and second gas supply units.

A pressure in the process chamber 445 or a partial pressure of a gas to be supplied may be adjusted by adjusting a supply rate of the gas or a gas exhaust rate of the process chamber 445 by controlling the mass flow controllers 482c and 483c and the pressure control valve 479.

In the gas buffer chamber 430, a porous shower plate 484 including a plate unit 484a and a plurality of hole units 484b formed in the plate unit 484a is installed. A gas supplied via a gas supply hole 343 collides against the plate unit 484a of the shower plate 484 and is then supplied onto a surface of the wafer 600 via the plurality of hole units 484b. The gas supplied as described is uniformly dispersed by the shower plate 484 and supplied onto the wafer 600.

The elements of the process unit 410 are electrically connected to and controlled by the controller 500. For example, the controller 500 controls the mass flow controllers 482c and 483c, the opening/closing valves 482d and 483d, the pressure control valve 479, the lifting driving unit 490, etc. The controller 500 also controls a heater temperature control unit 485 and a coolant flow rate controller 486 which will be described below.

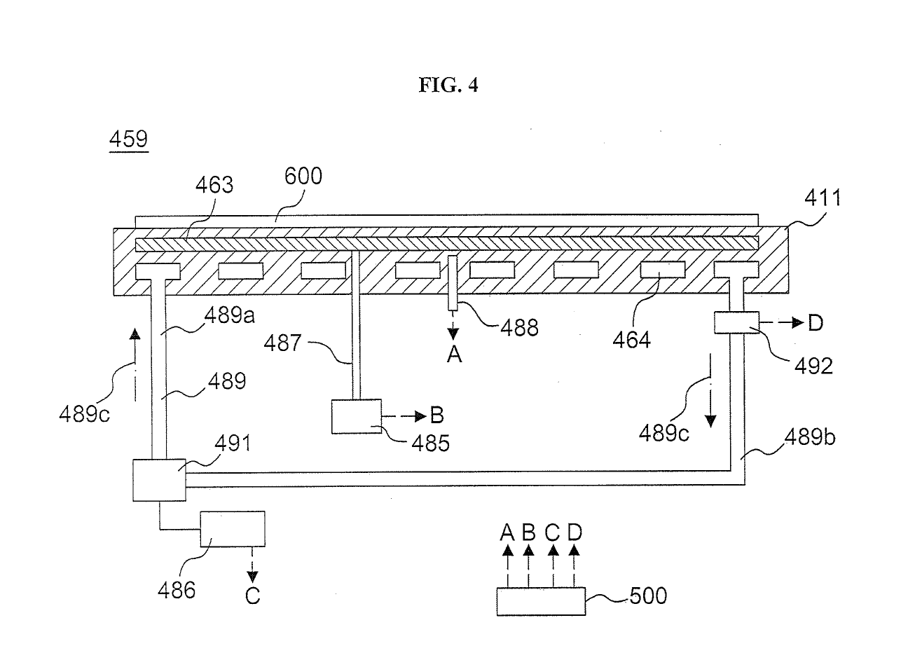

FIG. 4 is a detailed diagram of the susceptor 459. The heater 463 and the susceptor coolant channel 464 are embedded in the susceptor table 411. The heater 463 and the susceptor coolant channel 464 are installed in the susceptor table 411, and control the temperature of a wafer 600 placed on the susceptor 459.

The heater 463 is connected to the heater temperature control unit 485 via a heater power supply line 487. A temperature detector 488 is installed near the heater 463 to detect the temperature of the wafer 600 placed on the susceptor 459. The temperature detector 488 is electrically connected to the controller 500. Temperature data detected by the temperature detector 488 is input to the controller 500. The controller 500 controls the heater 463 to heat the wafer 600 to a desired temperature by instructing the heater temperature control unit 485 to control an amount of power to be supplied to the heater 463 based on the detected temperature data.

The susceptor coolant channel 464 is connected, via an external coolant channel 489, to a coolant source or a coolant flow rate control unit 491 including an element configured to control the flow rate of a coolant. A coolant flows in the susceptor coolant channel 464 or the external coolant channel 489 in a direction of an arrow 489c. A coolant temperature detector 492 configured to detect the temperature of the coolant flowing in the susceptor coolant channel 464 is installed at an upstream side of the coolant flow rate control unit 491. The coolant temperature detector 492 is electrically connected to the controller 500. Temperature data detected by the coolant temperature detector 492 is input to the controller 500. The controller 500 controls the flow rate of the coolant by instructing the coolant flow rate controller 486 to control the flow rate of the coolant based on the detected temperature data such that the wafer 600 has a desired temperature.

Although the heater temperature control unit 485 and the coolant flow rate controller 486 are described as separate elements in the present embodiment, the present invention is not limited thereto and the controller 500 may also act as the heater temperature control unit 485 and the coolant flow rate controller 486. The coolant flow rate controller 486 and the heater temperature control unit 485 are referred to as temperature control units. The heater 463 and the susceptor coolant channel 464 may be also referred to as temperature control units. Also, the coolant flow rate control unit 491, the external coolant channel 489, the coolant temperature detector 492 and the heater power supply line 487 may be also referred to as temperature control units. Also, the heater 463 and the susceptor coolant channel 464 are referred to as temperature adjustment mechanisms. As described above, the temperature of the wafer 600 is controlled by the temperature control units and the temperature adjustment mechanisms.

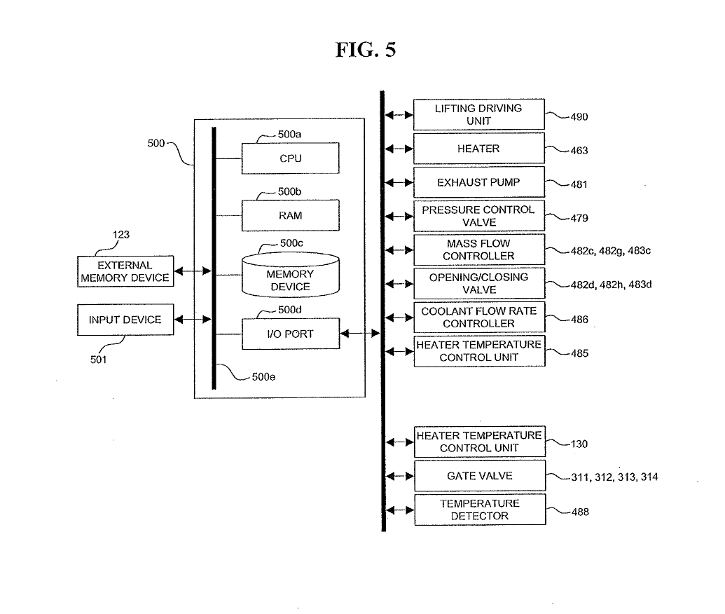

Next, the structure of the controller 500 will be described in detail. As illustrated in FIG. 5, the controller 500 which is a control unit (control means) may be embodied by a computer including a central processing unit (CPU) 500a, a random access memory (RAM) 500b, a memory device 500c and an input/output (I/O) port 500d. The RAM 500b, the memory device 500c and the I/O port 500d are configured to exchange data with the CPU 500a via an internal bus 500e. The controller 500 is connected to an input device 501 such as a touch panel or the like.

The memory device 500c may be embodied by a flash memory, a hard disk drive (HDD), or the like. In the memory device 500c, a control program for controlling an operation of a substrate processing apparatus, a process recipe including a substrate processing order or conditions, etc. is stored to be readable. Also, process conditions matching the type of each etching gas are memorized in the memory device 500c. Hereinafter, the process conditions refers to conditions of processing a substrate, such as a range of temperatures of a wafer or susceptor, a pressure in a process chamber, a partial pressure of a gas, a supply rate of a gas, a flow rate of a coolant, a process time, etc.

Also, the process recipe is a combination of sequences of a substrate processing process which will be described below to obtain a desired result when the sequences are performed by the controller 500, and acts as a program. Hereinafter, the process recipe, the control program, etc. will also be referred to together simply as a “program.” Also, when the term “program” is used in the present disclosure, it should be understood as including only the process recipe, only the control program, or both of the process recipe and the control program. Also, the RAM 500b serves as a memory area (work area) in which a program or data read by the CPU 5000a is temporarily stored.

The I/O port 500d is connected to the lifting driving unit 490, the heater temperature control unit 485, the pressure control valve (APC valve) 479, the mass flow controllers 482c, 482g and 483c), the opening/closing valves 482d, 482h and 483d, the exhaust pump 481, the standby transfer robot 130, the gate valves 313 and 314, the vacuum arm robot unit 320 and the coolant flow rate controller 486 described above, and the like.

The CPU 500a is configured to read and execute the control program from the memory device 500c and to read the process recipe from the memory device 500c according to a manipulation command or the like received via the input device 501. Also, the CPU 500a is configured to, based on the read process recipe, control the lifting driving unit 490 to move the lifter pins 413 upward/downward, control the heater 463 to heat the wafer 500, control the APC valve 479 to adjust a pressure, control the mass flow controllers 482c, 482g and 483c and the opening/closing valves 482d, 482h and 483d to adjust a flow rate of a process gas, etc.

Also, the controller 500 is not limited to a dedicated computer and may be embodied by a general-purpose computer. For example, the controller 500 according to the present embodiment may be provided with an external memory device 123 storing a program as described above, e.g., a magnetic disk (e.g., a magnetic tape, a flexible disk, a hard disk, etc.), an optical disc (e.g., a compact disc (CD), a digital versatile disc (DVD), etc.), a magneto-optical (MO) disc or a semiconductor memory (e.g., a Universal Serial Bus (USB) memory (a USB flash drive), a memory card, etc.), and then installing the program in a general-purpose computer using the external memory device 123. However, a means for supplying the program to a computer is not limited to using the external memory device 123. For example, the program may be supplied to a computer using a communication means, e.g., the Internet or an exclusive line, without using the external memory device 123. The memory device 500c or the external memory device 123 may be embodied by a non-transitory computer-readable recording medium. Hereinafter, the memory device 500c and the external memory device 123 may also be referred to together simply as a “recording medium.” When the term “recording medium” is used in the present disclosure, it may be understood as only the memory device 500c, only the external memory device 123, or both of the memory device 500c and the external memory device 123.

(Substrate Processing Method)

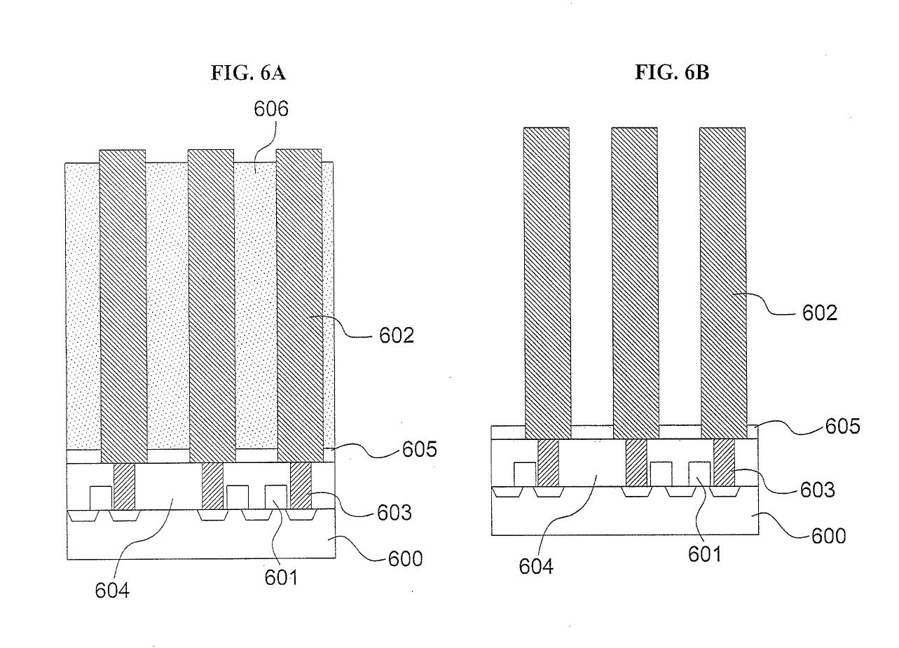

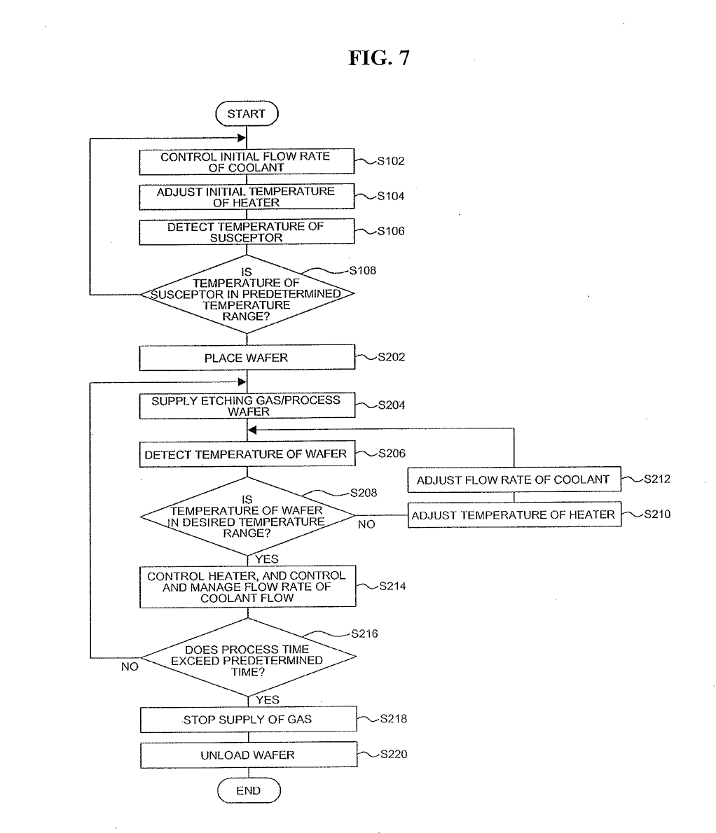

Next, an exemplary substrate processing method using a substrate processing apparatus according to the present invention will be described with reference to FIGS. 6A, 6B and 7 below. Operations of elements of the substrate processing apparatus are controlled by the controller 500.

(Description of Wafer to be Processed)

A film formed on a wafer 600 to be processed according to the present embodiment will be described with reference to FIGS. 6A and 6B below. FIGS. 6A and 6B are diagrams illustrating the structure of a device formed in a process of forming a dynamic random access memory (DRAM) which is a type of semiconductor memory. FIG. 6A illustrates a structure of a device before etching is performed according to the present embodiment. FIG. 6B illustrates a structure of the device after etching is performed according to the present embodiment. In the etching according to the present embodiment, a silicon (Si)-containing third layer 606 which is a sacrificial film and will be described below is removed. The third layer 606 is a film containing silicon as a main material.

On a wafer 600, a gate electrode, a lower electrode of a capacitor containing a metal as a main material, a sacrificial film used to form the lower electrode of the capacitor, and the like are formed. A film containing, as a main material, a metal used to form the lower electrode of the capacitor has a silicon content ratio lower than that of the sacrificial film. In the present embodiment, a process of removing the sacrificial film (an etching process) is performed. The term “silicon content ratio” refers to a ratio of silicon in a composition ratio of a film.

Hereinafter, an etching process according to the present invention will be described in detail. On the wafer 600, a plurality of gate electrodes 601 are formed, and a source and a drain are formed below left and right sides of each of the plurality of gate electrodes 601. A plug 603 connected to a lower electrode 602 of a capacitor is electrically connected to one of the source and the drain. The lower electrode 602 is embodied by a cylindrical pillar and having a cylindrical shape from which an inner circumference is cut out since the area of a dielectric film to be formed increases in a process which will be described below. For example, titanium nitride (TiN) is used as a material of the lower electrode 602.

A first layer 604 including the gate electrode 601, the plug 603 and a bit line electrode (not shown) therein is formed as an insulating film for insulating between electrodes or the like. A second layer 605 which is an etching stopper film is formed on the first layer 604. The third layer 606 which is a sacrificial film and which contains silicon (Si) as a main material is formed on the second layer 605 and around the lower electrode 602. After the sacrificial film is etched, a dielectric film is formed on an inner circumference of the lower electrode 602 and an outer circumference of the lower electrode 602 which is exposed by etching.

In the related art, the third layer 606 is removed by wet etching. However, as patterns have recently been developed to be finer, the strengths of the patterns are weak. Thus, when the third layer 606 is wet-etched, a pattern of the third layer 606 may collapse due to pressure caused by an etching solution. Thus, a process of etching a fine pattern is required to be performed without collapsing the pattern.

(Substrate Processing Method)

In the present embodiment, an etching gas is used so as not to collapse a fine pattern. An etching method will be described with reference to FIG. 7 below.

[Initial Coolant Flow Rate Controlling Process (S102)] A coolant supply unit 486 controls the coolant flow rate control unit 491 to circulate a coolant, which is adjusted to a preset liquid measure and temperature, between an external coolant channel 489a, the susceptor coolant channel 464 and a coolant channel 489b in the direction of the arrow 489c.

[Initial Heater Temperature Adjusting Process (S104)]

The heater temperature control unit 485 heats the heater 463 to a desired temperature by supplying a preset initial amount of power to the heater 463.

[Susceptor Temperature Detecting Process (S106)]

After the initial coolant flow rate controlling process (S102) and the initial heater temperature adjusting process (S104) are performed, the temperature detector 488 detects the temperature of the susceptor 459. Information regarding the detected temperature of the susceptor 459 is input to the controller 500.

[Susceptor Temperature Determining Process (S108)]

When the information regarding the detected temperature is in a predetermined temperature range, i.e., when ‘Yes’, the controller 500 controls a subsequent substrate placing process (S202) to be performed.

When the information regarding the detected temperature is not in the predetermined temperature range, i.e., when ‘No’, the initial coolant flow rate controlling process (S102), the initial heater temperature adjusting process (S104) and a subsequent susceptor temperature detecting process are repeatedly performed until the susceptor 459 has a temperature in the predetermined temperature range.

The processes S102 to S108 are preparatory steps before the wafer 600 is to be processed. Hereinafter, the processes S102 to S108 are referred to as initial processes.

[Wafer Placing Process (S202)]

When the temperature of the susceptor 459 is in the predetermined temperature range, the finger 321 of the vacuum aim robot unit 320 transfers the wafer 600 to the process chamber 445. In detail, the finger 321 on which the wafer 600 is placed enters the process chamber 445, and places the wafer 600 on the lifter pins 413 moved upward. A front end of the lifter pin 413 is maintained to be elevated from the susceptor table 411. The wafer 600 is received in a state of the wafer 600 being elevated on the lifter pin 413, i.e., from the susceptor table 411.

[Etching Gas Supplying/Wafer Processing Process (S204)]

When the wafer 600 is placed, the wafer 600 is heated and maintained to be in a predetermined temperature range (which will be described below) by a temperature control unit. Hereinafter, the predetermined temperature range refers to a temperature range in which an etching gas maintains to have high selectivity even when the etching gas does not obtain strong energy from the outside. For example, the predetermined temperature range ranges from room temperature (about 20° C.) to 130° C. in the case of xenon difluoride, and ranges from 30° C. to 100° C. in the case of iodine heptafluoride. In this case, a lower limit of the temperature range is determined by considering, for example, temperature controllability or temperature at which a gas cannot be liquefied.

Hereinafter, the strong energy obtained from the outside refers to, for example, high-frequency power supplied to the etching gas. When the high-frequency power is supplied to the etching gas, the etching gas attains a plasma state and etching may be performed using the etching gas that is in the plasma state. However, when etching is performed using the etching gas that is in the plasma state, plasma-induced damage may occur on the wafer 600, thereby degrading the quality of a circuit. The plasma-induced damage is damage caused by, for example, charging, ions, or the like.

Thus, a temperature range is controlled to a desired temperature range so that etching having high selectivity may be performed on a substrate including a film, the quality of which is degraded due to plasma-induced damage, by using a gas that is in a non-plasma state. The film, the quality of which is degraded due to plasma-induced damage refers to, for example, a circuit or electrode formed of a metal.

Also, the “high selectivity” refers to increasing an etching ratio of a first film containing, for example, silicon as a main material (hereinafter referred to as a silicon film) to be higher than an etching ratio of a second film (e.g., a film containing a metal as a main material) having a silicon content ratio lower than that of the first film. In detail, the “high selectivity” refers to increasing an etch speed of a silicon film to be faster than that of the second film. More preferably, the “high selectivity” refers to etching the silicon film without etching the second film. By etching the silicon film without etching the second film, the wafer 600 including a lower electrode of a capacitor having a high aspect ratio may be etched without causing a residue to occur in the wafer 600.

Next, a nitrogen gas serving as a dilution gas is supplied into the process chamber 445 by controlling the second gas supply unit 483. An etching gas is supplied from the gas introduction port 433 into the process chamber 445 by controlling the first gas supply unit 482 simultaneously with the supplying of the nitrogen gas into the process chamber 445. That is, the etching gas is supplied to the substrate. As the etching gas, chlorine trifluoride (ClF₃), xenon difluoride (XeF₂), bromine trifluoride (BrF₃), bromine pentafluoride (BrF₅), iodine heptafluoride (IF₇), or iodine pentafluoride (IF₅) is used. The supplied etching gas collides against the plate unit 484a of the shower plate 484, so that the etching gas may be supplied in a diffused state to the wafer 600 via the plurality of hole units 484b. Since the etching gas is supplied to the wafer 600 by diffusing the etching gas, etching may be uniformly performed within a plane of the wafer 600 (a third film 306 in the present embodiment).

Each gas supply unit is set to have a predetermined gas flow rate that is in a range of 0.1 slm to 10 slm. For example, the predetermined gas flow rate is set to 3 slm. An inside pressure of the process chamber 445 is set to be equal to a predetermined pressure that is in, for example, a range of 1 Pa to 1,300 Pa. For example, the inside pressure of the process chamber 445 is set to 100 Pa.

Also, the etching gas has a property of generating heat when the etching gas is in contact with a silicon film and reacts with the silicon film. Heat of the reaction is transferred to a metal film or a substrate through heat conduction. As a result, the characteristics of the metal film may be degraded or the substrate may be deformed. Also, a case in which the temperature of the wafer 600 is out of a predetermined temperature range and thus the high selectivity of the etching gas is lost may be considered.

The concentration and etching rate of the etching gas are in a proportional relation. Also, the etching rate and calories of reaction of the etching gas are in a proportional relation. Thus, when the etching rate of the etching gas is increased by increasing the concentration of the etching gas, the above phenomenon becomes more conspicuous.

Thus, a dilution gas is supplied into the process chamber 445 together with the etching gas to decrease the concentration of the etching gas, thereby suppressing the temperature of the etching gas from being excessively increased due to the heat of reaction. For example, a supply rate of the dilution gas is set to be higher than that of the etching gas.

Here, the dilution gas and the etching gas are supplied almost simultaneously, but the present invention is not limited thereto, and more preferably, the etching gas may be supplied after supplying of the dilution gas. This embodiment is advantageous in a case where the etching gas contains a heavier material (e.g., halogen) than the dilution gas and may etch without obtaining strong energy from the outside. For example, when a gas containing halogen and the dilution gas are simultaneously supplied, the gas containing halogen reaches a substrate earlier than the dilution gas. That is, the etching gas having a higher concentration reaches an upper portion of the substrate earlier than the dilution gas. In this case, the substrate is rapidly etched and thus the temperature thereof sharply increases. Thus, the high selectivity of the etching gas may be lost. To prevent this problem, the etching gas is preferably supplied to the substrate after the dilution gas is supplied to the substrate.

More preferably, the etching gas is supplied after an inside pressure of the process chamber 445 is stabilized in a state in which the process chamber 445 is filled with a dilution gas atmosphere. This method is effective when the amount of the dilution gas is sufficiently greater than that of the etching gas, for example, a process of controlling the depth of etching, etc. Since etching is performed in the state in which the inside pressure of the process chamber 445 is stabilized, the etching rate may be stabilized. Accordingly, the depth of etching may be easily controlled.

Also, in the present embodiment, while the etching gas is in contact with the wafer 600, maintaining a high etching rate, preventing the characteristic of a film of a substrate from being degraded, preventing the substrate from being deformed, maintaining high selectivity, or a combination thereof may be achieved by maintaining the temperature of the wafer 600 to be in a desired temperature range.

[Wafer Temperature Detecting Process (S206)]

As described above, while the etching gas is in contact with the wafer 600, the wafer 600 is heated by the heat of reaction. Here, the temperature of the wafer 600 heated by the heat of reaction is detected by the temperature detector 488.

[Wafer Temperature Determining Process (S208)]

Data regarding the temperature detected in the wafer temperature detecting process (S206) is input to the controller 500. The controller 500 determines whether the data regarding the detected temperature is in a desired temperature range. When the data regarding the detected temperature is in the desired temperature range, i.e., when ‘Yes’, a heater control & coolant flow rate control and management process S214 is performed. When the data regarding the detected temperature is not in the desired temperature range, i.e., when ‘No’, processes (S210 and S212) of controlling a temperature control unit are performed so that the temperature of the wafer 600 may be a desired temperature.

[Heater Temperature Adjusting Process (S210)]

When it is determined in the wafer temperature determining process (S208) that the temperature of the wafer 600 is not in the predetermined temperature range, the heater temperature control unit 485 controls an amount of power to be supplied to the heater 463. In the present embodiment, since the temperature of the wafer 600 increases to a temperature higher than an upper limit of the predetermined temperature range due to the heat of reaction, the temperature of the heater 463 is decreased to maintain the wafer 600 at a desired temperature.

[Coolant Flow Rate Adjusting Process (S212)]

When it is determined that the temperature of the wafer 600 is not in the predetermined temperature range, the coolant flow rate controller 486 controls the flow rate or temperature of a coolant. In the present embodiment, since the temperature of the wafer 600 increases to a temperature higher than the upper limit of the predetermined temperature range due to the heat of reaction, the flow rate of the coolant is increased or the temperature of the coolant is decreased to maintain the wafer 600 at a desired temperature, thereby increasing the efficiency of cooling the wafer 600.

As in the heater temperature adjusting process (S210) or the coolant flow rate adjusting process (S212), the temperature of the wafer 600 may be adjusted to be in the predetermined temperature range by controlling the heater 463 and the flow rate of the coolant. After the temperature of the wafer 600 is adjusted, the wafer temperature detecting process (S206) is repeatedly performed until the temperature of the wafer 600 is in the predetermined temperature range.

Also, although the coolant flow rate adjusting process (S212) is performed after the heater temperature adjusting process (S210) in the present embodiment, the present invention is not limited thereto. For example, the coolant flow rate adjusting process (S212) may be performed after the wafer temperature determining process (S208), and then the heater temperature adjusting process (S210) may be performed. Alternatively, the heater temperature adjusting process (S210) and the coolant flow rate adjusting process (S212) may be performed in parallel after the wafer temperature determining process (S208).

Also, although in the present embodiment, the temperature of the heater 463 is decreased to increase the flow rate of the coolant so as to decrease the temperature of the wafer 600, the present invention is not limited thereto, and the temperature of the heater 463 and the flow rate of the coolant may be controlled together to decrease the temperature of the wafer 600.

Also, when the temperature of the wafer 600 is lower than a lower limit of a desired temperature range, the temperature of the heater 463 and the flow rate of the coolant may be controlled together to increase the temperature of the wafer 600.

[Heater Control & Coolant Flow Rate Control and Management Process (S214)]

When it is determined in the wafer temperature determining process (S208) that the temperature of the wafer 600 is in the predetermined temperature range, the temperature of the heater 463 and the flow rate of the coolant may be continuously controlled to maintain the temperature of the wafer 600.

[Process Time Determining Process (S216)]

It is determined whether a process time exceeds a predetermined time. When it is determined that the process time exceeds the predetermined time, i.e., when ‘Yes’, a gas supply stopping process (S218) is performed. When it is determined that the process time does not exceed the predetermined time i.e., when ‘No’, the wafer 600 is continuously processed.

[Gas Supply Stopping Process (S218)]

When it is determined in the process time determining process (S216) that the process time exceeds the predetermined time, it is determined that etching of the wafer 600 is ended and thus the gas supply unit 482 is controlled to stop the supply of the etching gas. After the supply of the etching gas is stopped, the purge gas supply system of the gas supply unit 482 is controlled to discharge a residual gas from the gas supply pipe 482a so that the etching gas may not remain in the process chamber 445, and the gas supply unit 483 is controlled to supply an inert gas into the process chamber 445 so as to exhaust an atmosphere of the process chamber 445.

[Wafer Unloading Process (S220)]

After the supply of the etching gas is stopped, the wafer 600 is unloaded from the process chamber 445 in an order opposite to the order in which the wafer 600 is placed in the process chamber 445.

The wafer placing process (S202) to the wafer unloading process (S220) are referred together as a substrate processing process.

Representative effects achieved when the above processes are performed are as follows: (1) a fine pattern is prevented from collapsing since an etching gas applying a lower pressure to the fine pattern than a liquid chemical used to perform wet etching is used when the fine pattern is formed; (2) etching is maintained at a temperature enabling high selectivity and thus even a fine pattern having a high aspect ratio may be processed without badly influencing other films since etching is performed; (3) a silicon film may be removed from a substrate even including the silicon film and a metal film without degrading the characteristics of the metal film; and (4) etching is performed using a gas that is in a non-plasma state, thereby preventing plasma-induced damage from occurring.

### Second Embodiment

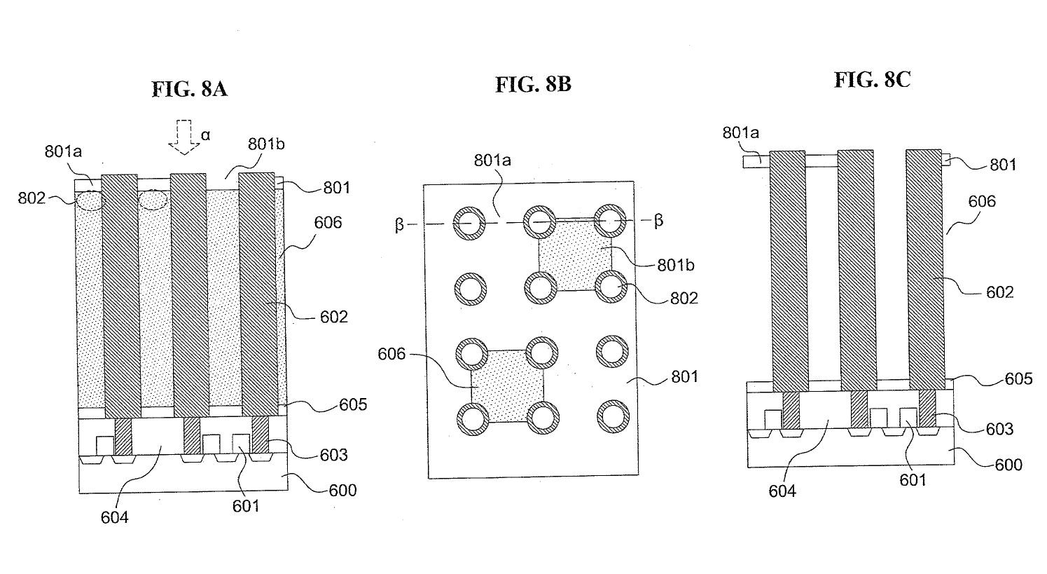

Next, a second embodiment will be described. The second embodiment is different from the first embodiment in that a device illustrated in FIGS. 8A through 8C is etched. The second embodiment will now be described focusing on the differences from the first embodiment.

FIGS. 8A through 8C are diagrams illustrating structures of a device to be etched according to the present embodiment. FIG. 8A is a cross-sectional view of the device taken along line 1343 of FIG. 8B. FIG. 8B is a view of the device of FIG. 8A when viewed in a direction of an arrow a, i.e., FIG. 8B is a top view of the device of FIG. 8A. FIG. 8C illustrates a structure of the device after etching is performed on the device according to the present embodiment. In the etching according to the present embodiment, a third layer 606 which is a sacrificial film and contains silicon (Si) is removed as will be described below. The third layer 606 is a film containing silicon as a main material.

A gate electrode, a lower electrode of a capacitor containing a metal as a main material, a sacrificial film used to form the lower electrode of the capacitor, an electrode support film, etc. are formed on a wafer 600. A film including, as a main material, a metal used to form the lower electrode of the capacitor and the electrode support film have a silicon content ratio lower than that of the sacrificial film. In the present embodiment, a process of removing the sacrificial film (an etching process) is performed.

An etching process according to the present invention will now be described in detail. A plurality of gate electrodes 601 are formed on the wafer 600, and a source and drain are formed below left and right sides of each of the plurality of gate electrodes 601. Plugs 603 respectively connected to lower electrodes 602 of the capacitor are electrically connected to one of the source and drain. Each of the lower electrode 602 is embodied by a cylindrical pillar, and has a cylindrical shape, the inner circumference of which is cut out since the area of a dielectric film increases in a subsequent process. For example, titanium nitride (TiN) is used as a material of the lower electrode 602.

A first layer 604 in which the gate electrodes 601 and the plugs 603 are embedded is formed of an insulating film for insulating between electrodes. A second layer 605 which is an etching stopper film is formed on the first layer 604. A third layer 606 which is a sacrificial film and contains silicon (Si) as a main material is formed on the second layer 605 and around the lower electrode 602. After the sacrificial film is etched, a dielectric film is formed on an inner circumference of the lower electrode 602 and an outer circumference of the lower electrode 602 exposed by etching.

An electrode support film 801 is formed between the lower electrode 602 to support side surfaces of the lower electrode 602. The electrode support film 801 is formed to cover a top surface of the third layer 606, and disperses a structural load of the lower electrode 602 when the sacrificial film 606 is removed.

The electrode support film 801 includes a plate unit 801a for connecting between the lower electrode 602 and a hole 801b formed in the plate unit 801a. The hole 801b is an introduction hole through which an etching gas is supplied below the plate unit 801a. As described above, an auxiliary structure preventing the lower electrode 602 from collapsing is formed.

The sacrificial film 606 may be etched by wet etching or plasma etching. However, when the sacrificial film 606 is etched by wet etching or plasma etching, the following problem occurs. When the sacrificial film 606 is etched by wet etching, an etching solution flows into the hole 801b. Thus, after the sacrificial film 606 is etched, the lower electrode 602 may collapse due to the viscosity of a liquid chemical or a surface tension applied thereto during a drying process of removing the etching solution.

When the sacrificial film 606 is etched by plasma etching, plasma that is in an active state should reach a lower portion of the sacrificial film 606 and thus an electrode into which plasma is injected should be formed on a susceptor having the wafer 600 thereon. Anisotropic etching is performed by an etching gas supplied into the electrode and thus plasma is not supplied to a location 802 right below the plate unit 801a. Thus, the third layer 606 which is a sacrificial film remains in the location 802 right below the plate unit 801a.

Therefore, in the present embodiment, an etching gas having high selectivity is used. As the etching gas, for example, chlorine trifluoride (ClF₃), xenon difluoride (XeF₂), bromine trifluoride (BrF₃), bromine pentafluoride (BrF₅), iodine heptafluoride (IF₇), or iodine pentafluoride (IF₅) is used.

Similar to the first embodiment, in the present embodiment, a temperature control unit is controlled to adjust the temperature of the wafer 600 to be in a predetermined temperature range. The etching gas supplied via the hole 801b is supplied to the location right below the plate unit 801a, thereby removing the sacrificial film from the location 802.

As described above, by processing with an etching gas within a predetermined temperature range, a pattern may be prevented from collapsing and the third layer 606 which is a sacrificial film may be etched without generating residues and etching the lower electrode 602 or the plate unit 801a.

A representative effect achieved when etching is performed as described above is as follows: (1) a film right below a film having an auxiliary structure may be removed from a substrate including a film having an auxiliary structure for preventing a pattern from collapsing without generating residues.

### Third Embodiment

Next, a third embodiment will be described. The third embodiment is different from the first embodiment in that a device including a film that is to be etched and the side cross-sectional area of which varies according to a depth thereof is etched. The third embodiment will now be described focusing on the differences from the first embodiment.

The device processed in the third embodiment includes a silicon-containing first film is to be etched and a second film having a silicon content ratio lower than that of the first film. A side cross-sectional area of the first film to be etched increases as it is closer to a wafer 600. If the amount of an object to be etched increases, the amount of the heat of reaction also increases. Thus, when portions having large side cross-sectional areas of the first film is etched, the temperature of the wafer 600 sharply increases. The first film is a film having silicon as a main material.

In this case, as the temperature of the wafer 600 sharply increases, the temperature of the wafer 600 is out of a predetermined temperature range and thus high selectivity of etching may be lost. Thus, the temperature of the wafer 600 should be adjusted to be in the predetermined temperature range according to a sharp increase in the temperature of the wafer 600.

In the present embodiment, when it is determined in the wafer temperature determining process (S208) that the temperature of the wafer 600 detected during the wafer temperature detecting process (S206) is out of the predetermined temperature range, the heater 463 is first controlled for the following reasons.

In the present embodiment, the heater 463 and the susceptor coolant channel 464 are used to control the temperature of the wafer 600. A coolant flowing into the susceptor coolant channel 464 is controlled by the coolant flow rate controller 486. For example, the flow rate of the coolant is controlled to be increased when it is determined that the temperature of the wafer 600 is high, and controlled to be decreased when it is determined that the temperature of the wafer 600 is low. As described above, the temperature of the wafer 600 is adjusted by controlling the flow rate of the coolant cooled when the coolant circulates in the external coolant channel 489.

The heater 463 may be embodied by a resistance heater, and the temperature thereof may be adjusted according to an amount of power supplied thereto. Thus, when the temperature of the wafer 600 is sharply increased, the temperature of the wafer 600 is preferably controlled by controlling not only the flow rate or temperature of the coolant flowing in the susceptor coolant channel 464 but also controlling a heater having a high capability of tracking a change in the temperature of the wafer 600. Thus, in the present embodiment, a heater is first controlled to handle a sharp increase in the temperature of the wafer 600.

Also, in the present embodiment, an etching gas having high selectivity is used. As the etching gas, chlorine trifluoride (ClF₃), xenon difluoride (XeF₂), bromine trifluoride (BrF₃), bromine pentafluoride (BrF₅), iodine heptafluoride (IF₇), or iodine pentafluoride (IF₅) is used.

A representative effect achieved when etching is performed as described above is as follows: (1) high selectivity may be maintained in even a device including a film that is to be etched and the side cross-sectional area of which varies according to a depth thereof.

### Fourth Embodiment

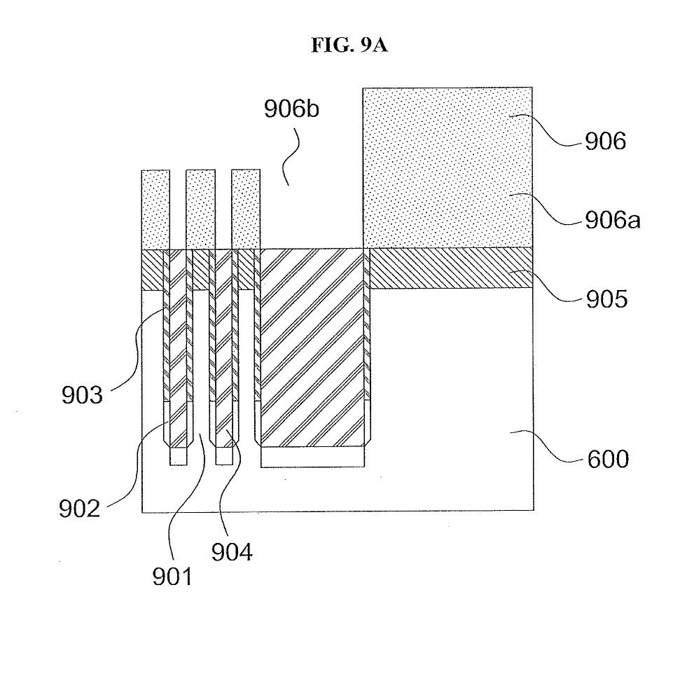

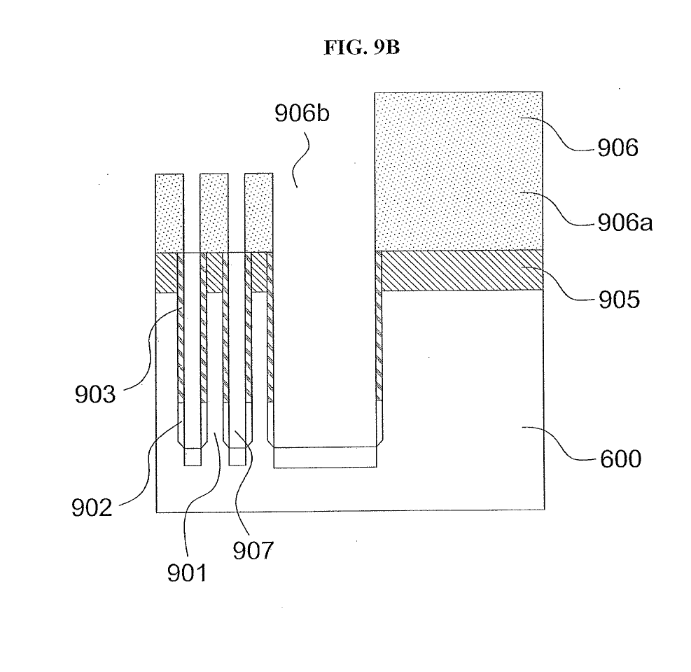

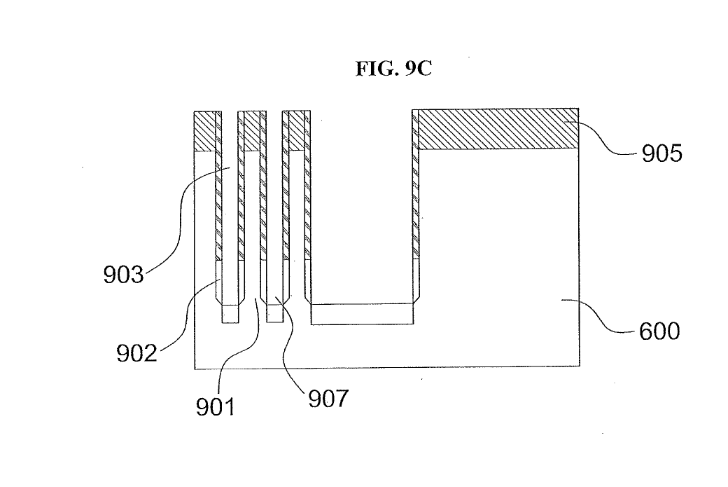

Next, a fourth embodiment will be described. The fourth embodiment is different from the first embodiment in that a device illustrated in FIGS. 9A through 9C is etched. In the device of FIGS. 9A through 9C, a silicon hard mask has different heights due to the loading effect when a resist film is removed. The fourth embodiment will be described focusing on the differences from the first embodiment below.

FIGS. 9A through 9C are diagrams illustrating structures of a device to be etched according to the present embodiment. FIG. 9A is a cross-sectional view of the device. FIG. 9B illustrates a structure of the device after an auxiliary film 904 is etched using a second hard mask pattern 906 of FIG. 9A. FIG. 9C illustrates a structure of the device after etching is performed according to the present embodiment. In the etching according to the present embodiment, the second hard mark pattern 906 is removed as will be described below.

The fourth embodiment will now be described in detail. A first film used as a hard mask, a second film used as an etching stopper film, or the like is formed on a wafer 600. The first film used as a hard mask contains silicon as a main material. The second film used as an etching stopper film has a silicon content ratio lower than that of the first film used as a hard mask. In the present embodiment, a process of removing a hard mask (an etching process) is performed. Hereinafter, the etching process according to the embodiment will be described.

FIGS. 9A through 9C are cross-sectional views of a device to be etched according to the present embodiment. Hereinafter, a method of forming a vertical transistor will be described as an example. In FIG. 9A, surround gates 902 formed around lower portions of vertical pillars 901 and spacers 903 formed on the vertical filler 901 are formed on the wafer 600. The strength of the fine vertical pillar 901 is weak. Thus, in order to prevent the vertical pillars 901 from collapsing, an auxiliary film 904 is embedded between the vertical fillers 901. A first hard mask pattern 905 used to form grooves between the vertical pillars 901 according to the etching process is formed around upper portions of the spacers 903.

The second hard mask pattern 906 containing silicon as a major material is formed on the first hard mask pattern 905. A silicon content ratio of the spacer 903 or the first hard mask pattern 905 is set to be lower than that of the second hard mask pattern 906. The auxiliary film 904 is etched using the second hard mask pattern 906 as a mask to form grooves 907 without causing the vertical pillars 901 to collapse as illustrated in FIG. 9B. Thereafter, the second hard mask pattern 906 is removed during the etching process according to the present embodiment.

Here, a deviation occurs in the height of the second hard mask pattern 906 due to the loading effect when a resist film formed on the second hard mask pattern 906 and used as a mask is removed. The loading effect is a phenomenon that a film is removed at different speeds due to a pattern density of the wafer 600. The speed of removing the resist film is high when the pattern of the wafer 600 is sparse and is low when the pattern of the wafer 600 is dense. Thus, a hard mask has different heights under the influence of an etching gas when the resist film is removed. Otherwise, the second hard mask pattern 906 has different heights since it is formed at different speeds due to an underlying film when the second hard mask pattern 906 is deposited.

In the present embodiment, the second hard mask pattern 906 includes a hard mask 906a having a sparse pattern and a hard mask 906b having a dense pattern. The height of the hard mask 906a is higher than that of the hard mask 906b.

The second hard mask pattern 906 may be etched by wet etching or plasma etching. However, the following problem may occur when etching rates of films are the same when the second hard mask pattern 906 is etched by wet etching or plasma etching. First, when an etching time is set such that the hard mask 906a is removed without generating residues, the hard mask 906a and the hard mask 906b may be etched without generating residues but the vertical pillars 901 below the hard mask 906b are also etched to a great extent.

Second, when an etching time is set such that the hard mask 906b is removed without generating residues, the hard mask 906b may be etched without generating residues but a portion of the hard mask 906a may not be etched.

Thus, in the present embodiment, an etching gas having high selectivity is used. As the etching gas, chlorine trifluoride (ClF₃), xenon difluoride (XeF₂), bromine trifluoride (BrF₃), bromine pentafluoride (BrF₅), iodine heptafluoride (IF₇), or iodine pentafluoride (IF₅) is used.

Similar to the first embodiment, a temperature control unit is controlled to adjust the temperature of the wafer 600 to be in a predetermined range in the present embodiment.

An etching gas supplied above the wafer 600 is supplied to the hard mask 906a and the hard mask 906b and reacts with the second hard mask pattern 906 to etch the second hard mask pattern 906.

The etching gas has high selectivity, thus only the hard mask 906b is etched and the first hard mask pattern 905 of the spacers 903 are not etched even when the etching gas is supplied to the wafer 600 while the hard mask 906a is etched.

A representative effect achieved when the etching process is performed as described above is as follows: (1) an object to etched may be etched without influencing the structures of other devices even when the object has different heights due to the loading effect or the like.

### OTHER EMBODIMENTS

Although various embodiments have been described above in detail, the present invention is not limited thereto and may be embodied in many different forms without departing from the scope of the invention.

Although the above embodiments have been described with respect to an etching process, the present invention is not limited thereto and is also applicable to any process of selecting and removing a target film. For example, the present invention is applicable to an ashing process, a process of removing residues generated during an etching process, etc.

Also, in these embodiments, a film is processed using a gas that is in a non-plasma state but may be processed using a gas that is in a plasma state provided that the quality of the film is not degraded due to plasma-induced damage. In this case, a temperature control unit controls the film to have a temperature enabling high selectivity using the gas that is in the plasma state.

Also, a single-wafer type apparatus has been described as an example in the present embodiment but the present invention is also applicable to, for example, a vertical apparatus in which substrates are stacked. In this case, the temperature of a wafer is controlled by controlling a heater and the like except for a process chamber by a temperature control unit.

Also, in the present embodiment, the temperature of a substrate is adjusted using a heater and a coolant channel but the present invention is not limited thereto and the temperature of the substrate can be adjusted using a heater having high capability of tracking a change in the temperature of the substrate without using a coolant in a process that does not require fine temperature control.

Also, in the present embodiment, the temperature of a wafer is adjusted using a heater and a coolant channel, but the present invention is not limited thereto and the temperature of the wafer can be adjusted using a coolant without using the heater when an etching gas, of which the temperature of liquefaction is lower than room temperature. Otherwise, the temperature of the wafer can be adjusted using a temperature control mechanism having both of a cooling function and a heating function performed by adjusting the temperature of a liquid that circulates.

Also, in the present embodiment, a titanium nitride (TiN) layer which is a metal film has been described above as an example of a film having a lower etch speed than that of a silicon film, but the present invention is not limited and the present invention is also applicable to a structure formed of silicon oxide (SiO₂), silicon nitride (Si₃N₄), amorphous carbon (a-C), or a combination thereof.

According to the present invention, etching having high selectivity can be performed to form a high-quality fine pattern.

Hereinafter, preferred embodiments according to the present invention are supplementarily noted.

### Supplementary Note 1

According to an aspect of the present invention, there is provided a substrate processing apparatus including: a substrate support where a substrate including a first film containing at least silicon and a second film having a silicon content ratio lower than that of the first film is placed; a process chamber wherein the substrate support is disposed; a gas supply system configured to supply an etching gas to the substrate; a temperature control unit configured to control a temperature of the substrate such that an etch rate of the first film is higher than that of the second film while the etching gas is in contact with the substrate; and an exhaust system configured to exhaust an inner atmosphere of the process chamber.

### Supplementary Note 2

The substrate processing apparatus of Supplementary note 1, preferably, further includes a heater disposed in the substrate support, and the temperature control unit is further configured to control the heater to control the temperature of the substrate.

### Supplementary Note 3

The substrate processing apparatus of Supplementary note 1, preferably, further includes a coolant channel disposed in the substrate support and having a coolant flowing therein, and the temperature control unit is further configured to control a flow rate of the coolant supplied to the coolant channel.

### Supplementary Note 4

In the substrate processing apparatus of Supplementary note 1, preferably, the gas supply system includes a first gas supply system configured to supply the etching gas and a second gas supply system configured to supply an inert gas, and the first gas supply system and the second gas supply system are controlled such that the inert gas is supplied and then the etching gas is supplied with the inert gas present about the substrate.

### Supplementary Note 5

According to another aspect of the present invention, there is provided a substrate processing apparatus including: a substrate support where a substrate including a first film containing at least silicon and a second film having a silicon content ratio lower than that of the first film is placed; a process chamber wherein the substrate support is disposed; a gas supply system configured to supply an etching gas to the substrate; a heater disposed in the substrate support; a temperature control unit configured to control a temperature of the heater such that an etch rate of the first film is higher than that of the second film while the etching gas is in contact with the substrate; and an exhaust system configured to exhaust an inner atmosphere of the process chamber.

### Supplementary Note 6

In the substrate processing apparatus of Supplementary note 5, preferably, the second film includes a metal film.

### Supplementary Note 7

The substrate processing apparatus of Supplementary note 5, preferably, further includes a cooling mechanism disposed in the substrate support and having a coolant flowing therein, and the temperature control unit is further configured to control a supply of the coolant.

### Supplementary Note 8

In the substrate processing apparatus of Supplementary note 5, preferably, the gas supply system includes a first gas supply system configured to supply the etching gas and a second gas supply system configured to supply an inert gas, and the first gas supply system and the second gas supply system are controlled such that the inert gas is supplied and then the etching gas is supplied with the inert gas present about the substrate.

### Supplementary Note 9

According to still another aspect of the present invention, there is provided a substrate processing apparatus including: a substrate support where a substrate including a first film containing at least silicon and a second film having a silicon content ratio lower than that of the first film is placed; a process chamber wherein the substrate support is disposed; a gas supply system configured to supply an etching gas to the substrate; a heater disposed in the substrate support; a temperature control unit configured to control a temperature of the heater such that an etch rate of the first film is higher than that of the second film while the etching gas is in contact with the substrate; and an exhaust system configured to exhaust an inner atmosphere of the process chamber.

### Supplementary Note 10

According to yet another aspect of the present invention, there is provided a method of manufacturing a semiconductor device including: (a) loading a substrate including a first film containing at least silicon and a second film having a silicon content ratio lower than that of the first film in a process chamber; (b) supplying an etching gas, controlling a temperature of the substrate such that an etch rate of the first film is higher than that of the second film while the etching gas is in contact with the substrate, and exhausting an inner atmosphere of the process chamber; and (c) unloading the substrate from the process chamber.

### Supplementary Note 11

According to yet another aspect of the present invention, there is provided a substrate processing method including: (a) loading a substrate including a first film containing at least silicon and a second film having a silicon content ratio lower than that of the first film in a process chamber; (b) supplying an etching gas, controlling a temperature of the substrate such that an etch rate of the first film is higher than that of the second film while the etching gas is in contact with the substrate, and exhausting an inner atmosphere of the process chamber; and (c) unloading the substrate from the process chamber.

### Supplementary Note 12

According to yet another aspect of the present invention, there is provided a method of manufacturing a semiconductor device including: (a) loading a substrate including a sacrificial film containing at least silicon, pillar-shaped metal films surrounded by the sacrificial film and support films disposed on the sacrificial film between the pillar-shaped metal films in a process chamber; (b) supplying an etching gas, and controlling a temperature of the substrate such that an etch rate of the sacrificial film is higher than that of the pillar-shaped metal films while the etching gas is in contact with the substrate, and exhausting an inner atmosphere of the process chamber; and (c) unloading the substrate from the process chamber.

### Supplementary Note 13

According to yet another aspect of the present invention, there is provided a program for causing a computer to control a substrate processing apparatus to perform:

(a) loading a substrate including a first film containing at least silicon and a second film having a silicon content ratio lower than that of the first film in a process chamber;

(b) supplying an etching gas, controlling a temperature of the substrate such that an etch rate of the first film is higher than that of the second film while the etching gas is in contact with the substrate, and exhausting an inner atmosphere of the process chamber; and

(c) unloading the substrate from the process chamber.

What is claimed is:

1. A substrate processing apparatus comprising:
a substrate support where a substrate including a first film containing at least silicon and a second film having a silicon content ratio lower than that of the first film is placed;
a process chamber wherein the substrate support is disposed;
a gas supply system configured to supply an etching gas to the substrate;
a coolant channel disposed in the substrate support and having a coolant flowing therein;
a coolant flow rate controller configured to control a flow rate of the coolant supplied to the coolant channel;
a control unit configured to control at least the coolant flow rate controller such that a temperature of the substrate is maintained whereat an etch rate of the first film is higher than that of the second film while the etching gas is in contact with the substrate; and
an exhaust system configured to exhaust an inner atmosphere of the process chamber.

2. The substrate processing apparatus of claim 1, further comprising a heater disposed in the substrate support, wherein the control unit is further configured to control the heater to control the temperature of the substrate.

3. The substrate processing apparatus of claim 1, wherein the gas supply system comprises a first gas supply system configured to supply the etching gas and a second gas supply system configured to supply an inert gas, and
the control unit is configured to control the first gas supply system and the second gas supply system to: supply the inert gas; and then supply the etching gas with the inert gas present about the substrate.

4. The substrate processing apparatus of claim 1, further comprising a coolant temperature detector configured to detect a temperature of the coolant after passing through the coolant channel, wherein the control unit is further configured to control the coolant flow rate controller to control the flow rate of the coolant based on a temperature of the coolant detected by the coolant temperature detector.

5. A method of manufacturing a semiconductor device, comprising:
(a) placing a substrate including a first film containing at least silicon and a second film having a silicon content ratio lower than that of the first film on a substrate support in a process chamber;
(b) supplying an etching gas, controlling a flow rate of a coolant flowing in a coolant channel disposed in the substrate support such that a temperature of the substrate is maintained whereat an etch rate of the first film is higher than that of the second film while the etching gas is in contact with the substrate, and exhausting an inner atmosphere of the process chamber; and
(c) unloading the substrate from the process chamber.

6. The method of claim 5, further comprising controlling the temperature of the substrate by controlling a heater disposed in the substrate support.

7. A method of manufacturing a semiconductor device, comprising:
(a) placing a substrate including a sacrificial film containing at least silicon and a pillar-shaped metal film surrounded by the sacrificial film on a substrate support in a process chamber;
(b) supplying an etching gas, and controlling a flow rate of a coolant flowing in a coolant channel disposed in the substrate support such that a temperature of the substrate is maintained whereat an etch rate of the sacrificial film is higher than that of the metal film while the etching gas is in contact with the substrate, and exhausting an inner atmosphere of the process chamber; and
(c) unloading the substrate from the process chamber.
